(19) United States
(12) Patent Application Publication
(10) Pub. No.: US 2012/0313633 A1
(43) Pub. Date: Dec. 13, 2012

(54) PERFORMANCE-OPTIMIZED ACTIVATION OF A FLUXGATE SENSOR

(76) Inventors: Frank Schatz, Kornwestheim (DE); Fouad Bennini, Reutlingen (DE)

(21) Appl. No.: 13/497,336

(22) PCT Filed: Aug. 3, 2010
(86) PCT No.: PCT/EP2010/061313

§ 371 Date: Aug. 3, 2012

(30) Foreign Application Priority Data
Sep. 24, 2009 (DE) 102009044988.4

(51) Int. Cl. G01R 33/02

(52) U.S. Cl. 324/225

(57) ABSTRACT

A measuring device for measuring a magnetic field having a field coil which is situated around a soft magnetic core and connected to an excitation signal generator, and a detector coil which is situated around the soft magnetic core and connected to an evaluation unit, the excitation signal generator being designed for generating an excitation signal for generating a magnetic field and outputting it to the field coil, and the evaluation unit being designed for evaluating a measuring signal output by the detector coil. The excitation signal generator includes a DC signal generator and an AC signal generator connected in series to the DC signal generator.

### BACKGROUND INFORMATION

The principle of magnetic field measurement using fluxgate sensors is widely used in practice. The measuring principle is based on the alternating magnetic reversal of a soft magnetic core with the aid of a field coil and the detection of the time-dependent magnetic flux generated using a detector coil. The flux change is determined by the magnetization curve of the soft magnetic core as a function of the external magnetic field to be measured.

The faster the magnetic reversal, the greater is the voltage generated by the detector coil, making it possible to increase the voltage generated by the detector coil both by a steeper magnetic hysteresis by selecting a core having higher permeability, as well as by increasing the frequency of the field coil.

A conventional measuring method measures the point in time of the magnetic reversal based on the voltage fluctuation of the detector coil. This point in time depends on the external magnetic field and is thus a measure of the strength of the magnetic field to be measured.

The measuring range of the fluxgate sensor depends on the field voltage of the field coil. The higher the field voltage, the more room there is for a shift in the magnetic reversal, i.e., greater external magnetic fields may be measured. The relationship between the field voltage and the measurable size of the external magnetic field is almost linear.

In the case of practical applications, interference fields may be superposed on the magnetic field of interest. If these interference fields are constant and their size is known, they may be compensated for the measurement. It is, however, problematic that the interference fields may be very much greater than the magnetic field to be measured. In this case, the measuring range must be expanded in such a way that the sum of the interference field and the magnetic field to be measured may be measured. This means that the field voltage must also be increased accordingly, which results in a higher power consumption of the measuring device.

An object of the present invention is to reduce the power consumption of a fluxgate sensor measuring device for a magnetic field measurement under the influence of strong interference fields.

### SUMMARY

In accordance with the present invention, the field voltage is adjusted according to the acting external fields, so that the measuring range is not expanded, but rather shifted, thereby reducing the amplitude of the field voltage. Under the same measuring conditions, the power consumption is minimized in this way.

A first aspect of the present invention therefore introduces a measuring device for measuring a magnetic field having a field coil which is situated around a soft magnetic core and connected to an excitation signal generator, and a detector coil situated around the soft magnetic core and connected to an evaluation unit, the excitation signal generator being designed for generating an excitation signal for generating a magnetic field and outputting it to the field coil, and the evaluation unit being designed for evaluating a measuring signal output by the detector coil. According to the present invention, the excitation signal generator includes a DC signal generator for generating a constant excitation signal and an AC signal generator for generating an alternating excitation signal, the DC signal generator and the AC signal generator being interconnected to one another in such a way that the constant excitation signal and the alternating excitation signal are superposed.

The constant excitation signal causes the compensation of the known constant interference field during the measurement, while the amplitude of the alternating excitation signal may be reduced by as much as is allowed by the size of the magnetic field to be measured. As a result, the power consumption of the measuring device caused by the generation of the excitation signal is reduced significantly compared to the previously known case of an increase in the amplitude of the excitation signal.

Preferably, the DC signal generator is designed for generating the constant excitation signal having a selectable value. Alternatively or additionally, the AC signal generator may be designed for generating the alternating excitation signal having a selectable amplitude. The advantage of these circuitry measures is that the particular components of the excitation signal may be adapted to the circumstances of the particular magnetic field measurement.

It is preferred in particular that the AC signal generator is designed for generating the alternating excitation signal having a selectable amplitude which is greater than the constant excitation signal to be generated by the DC signal generator. This ensures that the excitation signal resulting from the superposition of the constant excitation signal and the alternating excitation signal always implements a magnetic reversal, on which the measuring principle is based. This may, for example, be implemented in that the AC signal generator and the DC signal generator are connected to one another and that the AC signal generator adds the absolute value of the selected magnitude of the constant excitation signal as well as, optionally, an offset value, to the absolute value of the selected amplitude. Depending on the external field, an excitation signal without a change of sign may also be used.

The AC signal generator and the DC signal generator may be implemented, for example, as series-connected voltage sources or as parallel-connected current sources.

A second aspect of the present invention introduces a measuring method for measuring a magnetic field, including the following steps:

generating an excitation signal and outputting the excitation signal to a field coil situated around a soft magnetic core;
converting the excitation signal into a magnetic field by the field coil; and converting the magnetic field into a measuring signal by a detector coil situated around the soft magnetic core and outputting the measuring signal to an evaluation unit.

According to an example embodiment of the present invention, a constant excitation signal and an alternating excitation signal are superposed on the excitation signal during the step of generating the excitation signal.

Advantageously, a value of the constant excitation signal and/or an amplitude of the alternating excitation signal may be predefinable.

It is preferred in particular that the amplitude of the alternating excitation signal is greater than a value of the constant excitation signal. Depending on the external field, an excitation signal without a change of sign may also be used.

### BRIEF DESCRIPTION OF THE DRAWINGS

The present invention will be explained in greater detail below with reference to the figures.

FIG. 1 shows the design of a fluxgate sensor.

FIG. 2 shows typical signal curves of the excitation signal and the measuring signal in three sub-figures.

FIG. 3 shows an example of a compensation of a known constant interference field according to the present invention while simultaneously showing an optimized power consumption of the measuring device in two sub-figures.

### DETAILED DESCRIPTION OF EXAMPLE EMBODIMENTS

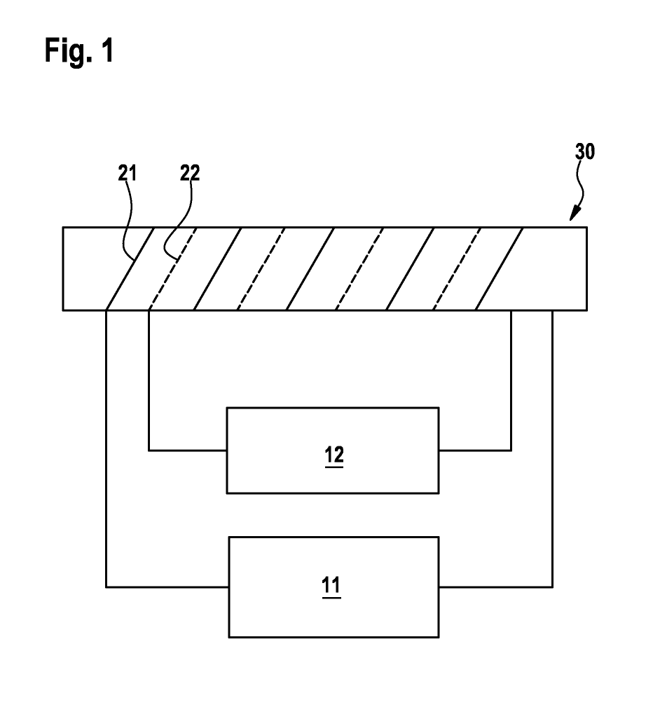

FIG. 1 shows the design of a fluxgate sensor. An excitation signal generator 11 is connected to both ends of a field coil 21 (solid line), which is situated around a soft magnetic core 30. Also situated around soft magnetic core 30 is a detector coil 22 (dashed line), whose two ends are connected to an evaluation unit 12. Field coil 21 and detector coil 22 are electrically insulated from one another and from soft magnetic core 30.

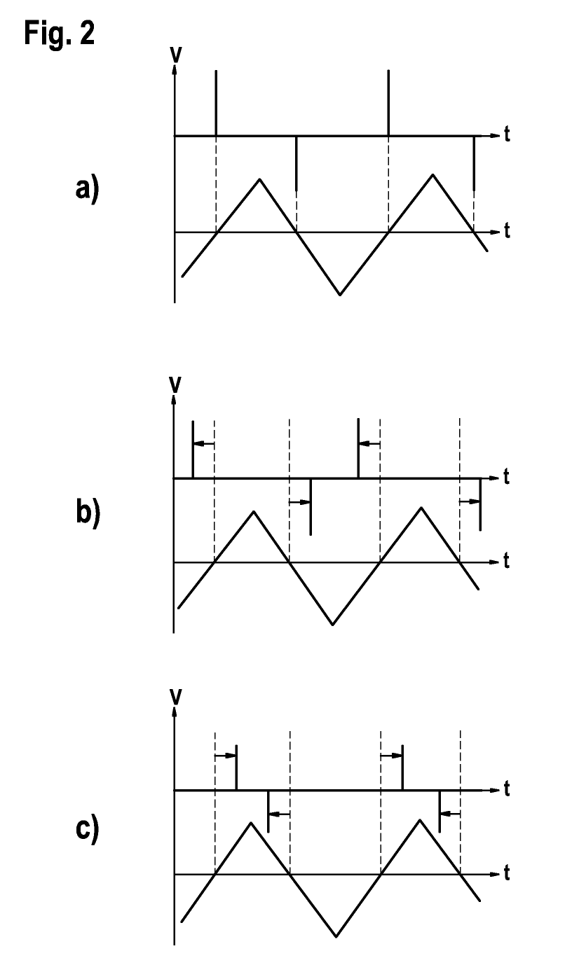

FIG. 2 shows typical signal curves of the excitation signal and the measuring signal in three sub-drawings. Sub-figure a) shows signal curves of the excitation signal (lower timeline) and the measuring signal (upper timeline) for the field-free case. At the points in time at which a change of sign or zero crossing of the excitation signal takes place, the measuring signal output by detector coil 22 shows a brief voltage fluctuation whose sign depends on the direction of the change of sign of the excitation signal.

Sub-figure b) shows corresponding signal curves for a case in which soft magnetic core 30 is penetrated by an external field which remains constant during the measuring process. Due to the superposition of the external field and the field generated by the excitation signal in soft magnetic core 30, the points in time of the brief voltage fluctuations of the measuring signal are shifted compared to those of the zero crossings, the direction of shift depending on the sign of the brief voltage fluctuation or the direction of the change of sign of the excitation signal, which is why pairs of voltage pulses approach one another. The shift over time of the brief voltage fluctuations is a measure of the strength of the external field.

If the external field is now so strong that the pairs of voltage pulses would coincide over time, there is no longer a magnetic reversal of soft magnetic core 30, so that the measuring principle fails. Conventionally, the amplitude of the excitation signal must be increased accordingly in this case, which greatly increases the power consumption.

Third sub-figure c) shows another case for a presence of an external field which has, however, a reversed sign compared to the case of sub-figure b). Again, the points in time of the brief voltage fluctuations of the measuring signal with respect to the zero crossings of the excitation signal are shifted, the direction of shift also being reversed due to the reversed sign of the external field.

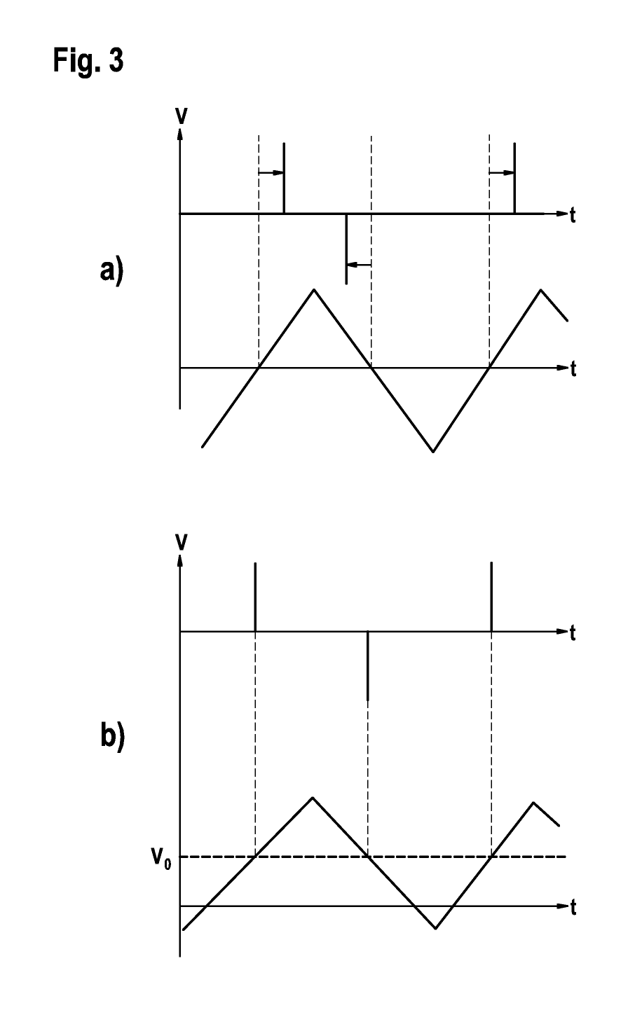

FIG. 3 shows an example of a compensation of a known constant interference field according to the present invention while simultaneously showing an optimized power consumption of the measuring device in two sub-figures. Sub-figure a) shows signal curves which correspond to those of sub-figure c) of FIG. 2. To be able to perform the measurement of the strong external field, the amplitude of the excitation signal must be correspondingly large. In the case of a measurement of a small field that is superposed by a strong known interference field, the amplitude of the excitation signal is therefore selected in the related art to be so large that it is possible to measure the small field plus the known strong interference field.

Sub-figure b) shows how, according to the present invention, the strong known interference field is compensated without simultaneously increasing the amplitude of the excitation signal beyond the degree required for measuring the small field. The excitation signal shown in the lower timeline of sub-figure b) has a DC component V₀, which is set in such a way that the strong known interference field is compensated in soft magnetic core 30. DC component V₀ is shown in sub-drawing b) as a horizontal dashed line. In the case shown, the small field to be measured is equal to 0, for which reason the points in time of the brief voltage fluctuations in the measuring signal coincide with those of the crossings of the AC component of the excitation signal through DC component V₀ (see vertical dashed lines). Compared to a measuring environment without an interference field, the amplitude of the excitation signal remains the same when the measuring principle according to the present invention is used; only the generation of DC component V₀ means a certain increase in the power consumption of the measuring device. Overall, however, the required power will be greatly reduced. Moreover, the number of measurements per unit of time or the frequency (of the AC component) of the excitation signal may be increased while keeping the steepness of the excitation signal (ΔV/Δt) constant, which, among other things, may also be utilized for improving the measuring result by averaging multiple measurements or for measuring rapidly changing fields.

1-10. (canceled)

11. A measuring device for measuring a magnetic field, comprising
a field coil situated around a soft magnetic core and connected to an excitation signal generator, the excitation signal generator configured to generate an excitation signal for generating a magnetic field and to output the excitation signal to the field coil; and
a detector coil situated around the soft magnetic core and connected to an evaluation unit, the evaluation unit configured to evaluate a measuring signal output by the detector coil;
wherein the excitation signal generator includes a DC signal generator to generate a constant excitation signal and an AC signal generator to generate an alternating excitation signal, the DC signal generator and the AC signal generator are interconnected to one another in such a way that the constant excitation signal and the alternating excitation signal are superposed, and wherein the constant excitation signal compensates for a constant interference field present on the measuring device.

12. The measuring device as recited in claim 11, wherein the DC signal generator is configured to generate the constant excitation signal having a selectable value.

13. The measuring device as recited in claim 11, wherein the AC signal generator is to generate the alternating excitation signal having a selectable amplitude.

14. The measuring device as recited in claim 12, wherein the AC signal generator is to generate the alternating excitation signal having a selectable amplitude which is greater than the constant excitation signal generated by the DC signal generator.

15. The measuring device as recited in claim 11, wherein the DC signal generator and the AC signal generator are voltage sources and connected in series to one another.

16. The measuring device as recited in claim 11, wherein the DC signal generator and the AC signal generator are current sources and connected in parallel to one another.

17. A method for measuring a magnetic field, comprising:
generating an excitation signal and outputting the excitation signal to a field coil situated around a soft magnetic core;
converting the excitation signal into a magnetic field by the field coil; and
converting the magnetic field into a measuring signal by a detector coil situated around the soft magnetic core and outputting the measuring signal to an evaluation unit;
wherein a constant excitation signal and an alternating excitation signal are superposed on the excitation signal during the generating the excitation signal step, and wherein the constant excitation signal compensates for a constant interference field present on the measuring device.

18. The method as recited in claim 17, wherein a value of the constant excitation signal is predefinable.

19. The method as recited in claim 17, wherein an amplitude of the alternating excitation signal is predefinable.

20. The method as recited in claim 18, wherein the amplitude of the alternating excitation signal is greater than a value of the constant excitation signal.
